(19) United States
(12) Patent Application Publication
(10) Pub. No.: US 2026/0132315 A1
(43) Pub. Date: May 14, 2026

(54) THERMALLY CONDUCTIVE DIE ATTACH FILM

(71) Applicant: Henkel AG & Co. KGaA, Duesseldorf (DE)

(72) Inventors: Junbo Gao, Irvine, CA (US); Qizhuo Zhuo, Irvine, CA (US); Elizabeth Hoang, Orange, CA (US); Xinpei Cao, Irvine, CA (US); Austin Iannuzzi, Riverside, CA (US); Kate M. Nguyen, Irvine, CA (US)

(21) Appl. No.: 19/429,002

(22) Filed: Dec. 22, 2025

Related U.S. Application Data
(63) Continuation of application No. PCT/US2024/034672, filed on Jun. 20, 2024.
(60) Provisional application No. 63/522,090, filed on Jun. 20, 2023.

(51) Int. Cl. C09J 7/30; C08K 3/08; C08K 5/18; C08K 5/21; C09J 5/06; C09J 163/00; H10W 40/20; H10W 40/25; H10W 72/00; H10W 72/30; H10W 90/00

(52) U.S. Cl. CPC C09J 7/30; C08K 3/08; C08K 5/18; C08K 5/21; C09J 5/06; C09J 163/00; H10W 40/242; H10W 40/251; H10W 40/257; H10W 72/07338; H10W 72/325; C08K 2003/0806; C08K 2201/001; C09J 2203/326; C09J 2301/50; C09J 2400/10; C09J 2463/00; H10W 90/734

(57) ABSTRACT

A thermally conductive curable composition is useful as a conductive die attach adhesive. The curable composition exhibits high thermal conductivity in excess of 5 W/m*K while also exhibiting relatively low melt viscosity over a broad temperature profile. The low melt viscosity facilitates good substrate wetting′ and adhesion properties in semiconductor die attach applications.

### FIELD

The present invention relates to thermally conductive adhesives generally, and more particularly to thermally conductive die attach films and curable compositions for the production of thermally conductive die attach films. The present invention further relates to electronic packages using the thermally conductive adhesives.

### BACKGROUND

Attachment of electronic components, such as semiconductor dies, to a substrate in an electronic package is typically accomplished through the use of an adhesive that bonds the electronic component to the substrate surface. Numerous adhesives have been used over the years for this purpose, and are known as die attach films. As electronic packages have become more complex with higher densities of components such as semiconductor chips, excess heat generated by the electronic components has become a challenging issue. Dissipation of the excess heat is essential for maintaining optimal electronic package performance.

Developers have employed inorganic particulate filler in adhesive resin compositions to enhance the thermal conductivity properties that are otherwise limited, particularly in the commonly-used thermoset polymer adhesive compositions. As the need for increased thermal dissipation capabilities have intensified with increased power and density of electronic components, die attach film thermal conductivity has been enhanced by increasing filler concentration. Doing so, however, decreases flowability of curable adhesive compositions, and increases brittleness in the cured film. Such characteristics lead to challenges in film lamination to the substrate surface, dicing, and die pick up processes.

It is therefore an aspect of the invention to provide a thermally conductive curable composition that exhibits high thermal conductivity while maintaining low melt viscosities.

It is another aspect of the invention to provide a die attach film that exhibits high thermal conductivity and good processing properties for manufacturing processes including lamination, wetting of the substrate, dicing, and die pick up.

### SUMMARY

By means of the present invention, a thermally conductive curable composition may be formed into a thermal dissipation body that is positionable between a heat source and a heat sink. The curable composition may be formed into an adhesive film for securing components within an electronic package. In one example, the composition may provide a thermally conductive die attach film with high thermal conductivity. The curable composition exhibits high flowability and low melt viscosities relative to conventional compositions of comparable thermal conductivity, which therefore enhances the wettability of large surface area substrates.

In one embodiment, a thermally conductive curable composition includes a curable resin component such as a curable epoxy resin, thermally conductive particulate filler present at less than 95 wt % by solids of the composition, and a curing agent effective to cure the curable resin component. The thermally conductive particulate filler may be selected from a metal, a metal alloy, a metal oxide, and combinations thereof. The curing agent may be selected so that the composition exhibits a polymerization onset temperature of at least 140° C. When cured, the composition exhibits a thermal conductivity of at least 5 W/m*K.

In some embodiments, the thermally conductive particulate filler is present at less than 85 wt % by solids of the composition.

In some embodiments, the thermally conductive particulate filler includes a metal selected from copper, silver, aluminum, and combinations thereof. In some embodiments, the thermally conductive particulate filler has a melting point of at least 300° C.

In some embodiments, the curing agent is a latent curing agent that does not react with the curable resin until a temperature threshold is exceeded. In some embodiments, the latent curing agent does not react with the curable resin at temperatures below 140° C.

In some embodiments, the curing agent includes at least one of an aromatic substituted urea and an aromatic amine.

In some embodiments, the curable composition has a melt viscosity change of less than 75% between 50-130° C. In some embodiments, the curable composition has a melt viscosity of less than 50000 Pa*s at 50° C.

In some embodiments, when cured, the composition exhibits a thermal conductivity of at least 10 W/m*K.

In another embodiment, a thermally conductive adhesive composition includes between 5 and 40 wt % by solids of a curable resin, between 0.1 and 2 wt % by solids of a curing agent effective to cure the resin, and less than 95 wt % by solids of a thermally conductive particulate metallic filler. The curing agent may be selected so that the composition exhibits a polymerization onset temperature of at least 140° C. When cured, the composition may exhibit a thermal conductivity of at least 6 W/m*K.

In some embodiments, the curable resin includes an epoxy. In some embodiments, the curable resin includes at least one of an acrylate, a bismaleimide, and combinations thereof.

In some embodiments, the thermally conductive particulate metallic filler includes silver.

In some embodiments, the curing agent includes at least one of an aromatic amine and an aromatic substituted urea.

In some embodiments, the thermally conductive adhesive composition includes less than 85 wt % by solids of the thermally conductive particulate metallic filler.

An electronic package of the present invention may include a silicon substrate, a thermally conductive curable composition applied to a surface of the silicon substrate, and an electronic component connected to the silicon substrate by the thermally conductive curable composition when in a cured condition. The thermally conductive curable composition may include a curable resin, thermally conductive particulate filler present at less than 95 wt % by solids of the composition, and a curing agent that is effective to cure the resin. The thermally conductive filler may be selected from a metal, a metal alloy, a metal oxide, and combinations thereof. The curing agent may be selected so that the composition exhibits a polymerization onset temperature of at least 140° C. When cured, the composition may exhibit a thermal conductivity of at least 5 W/m*K.

In some embodiments, the thermally conductive curable composition may be disposed as a film onto the surface of the silicon substrate.

### BRIEF DESCRIPTION OF THE DRAWINGS

FIG. 1 is a flow diagram illustrating a process flow for attaching a die to a semiconductor wafer using a thermally conductive adhesive.

FIG. 2 is a schematic illustration of an assembly using the thermally conductive curable compositions of the present invention.

FIG. 3 is a chart comparing melt viscosity over temperature as between the thermally conductive curable compositions of the present invention and conventional thermally conductive curable compositions.

FIG. 4 is a schematic illustration of a semiconductor chip utilizing the thermally conductive curable compositions of the present invention.

FIG. 5 is a schematic illustration of an electronic package utilizing a die attach film formed from the thermally conductive curable compositions of the present invention.

### DETAILED DESCRIPTION

The advantages enumerated above, for instance, are now described in terms of detailed embodiments. Other embodiments and aspects of the invention, however, are recognized as being within the grasp of those having ordinary skill in the art. Specifically, the features described with respect to the present compositions and apparatus may be combined in ways other than that described in the claims, as well as in ways other than that described in the specification.

A composition, and in some embodiments, an adhesive composition, such as for use in die attach applications is provided. The adhesive composition includes a curable resin component, a curing agent, and thermally conductive particulate filler. The curable resin may contain an epoxy resin, and, in such embodiments, the curing agent is effective in curing the epoxy resin.

The thermally conductive compositions of the present invention may be formed as a coating or film on a substrate, typically as an adherent along a thermal dissipation pathway, such as between a heat-generating electronic component and a substrate to which the component is attached. The thermally conductive compositions of the present invention may be suitable as a die attach film, sometimes referred to as a Conductive Die Attach Film (“CDAF”), in electronic packages for securing “dies”, such as processors, power semiconductor devices, and the like, to a silicon wafer substrate. The compositions preferably exhibit sufficient wettability to coat the respective substrate surface prior to curing. When cured, the thermally conductive film preferably exhibits a high thermal conductivity of at least 5 W/m*K, and in some embodiments at least 10 W/m*K.

The thermally conductive compositions of the present invention may preferably be 1-part curable compositions that are activated at elevated temperatures. The curable compositions are therefore stable at room temperature, and are curable upon the application of sufficient heat. The curable compositions may be curable through an agent facilitated pathway, wherein the one or more curing agents present in the composition become active only above a minimum temperature threshold. Such curing agents are sometimes referred to as latent curing agents.

### Resin Matrix Material

The thermally conductive interface materials of the present invention comprise a matrix formed from at least a curable resin component and a chemical curing agent, wherein the term “resin” may include any natural or synthetic organic compound or mixture that is convertible into a polymer. Preferably, a cure reaction is initiated with exposure between the curable resin component and the curing agent, in some cases when in the presence of an environmental cure reaction facilitator, such as water, heat, pressure, electromagnetic radiation, and the like. In preferred embodiments, the cure reaction is initiated with exposure between the curable resin component and the curing agent in the presence of heat, and particularly temperatures above a minimum threshold.

The curable resin component may be any curable resin, and is preferably a thermosetting polymeric material that cures through the application of heat. Examples of useful curable resins include epoxies, maleimides, (meth)acrylates, and the like. If the resin component is selected to include an epoxy, the resin may be any of a liquid, solid, semi-solid, and a solid dissolved or suspended in a liquid such as a solvent, each at room temperature. The curable resin component may include a combination of epoxy resins that are curable into a film of desired properties.

A wide variety of epoxy-functionalized resins are contemplated for use in the curable compositions of the present invention. For example, liquid-type epoxy resins based on bisphenol A, liquid-type epoxy resins based on bisphenol F, multifunctional epoxy resins based on phenol novolac resin, dicyclopentadiene-type epoxy resins, naphthalene-type epoxy resins, and the like. Other example epoxy-functionalized resins contemplated for use herein include the diepoxide of the cycloaliphatic alcohol, hydrogenated bisphenol A (commercially available as Epalloy 5000), a difunctional cycloaliphatic glycidyl ester of hexahydrophthallic anhydride (commercially available as Epalloy 5200), Epiclon EXA-835LV, Epiclon HP-7200L, and the like, as well as mixtures of any two or more thereof.

In some embodiments, the curable composition may include a combination of two or more different epoxy-functionalized resins, including two or more different bisphenol-based epoxies. The bisphenol-based epoxies may be selected from bisphenol A, bisphenol F, or bisphenol S epoxies, and combinations thereof. In addition, two or more different bisphenol epoxies within the same type of resin (such A, F, or S) may be used.

Commercially available examples of the bisphenol epoxies contemplated for use herein include bisphenol-F-type epoxies (such as RE-404-S from Nippon Kayaku, Japan, and EPICLON 830 (RE1801), 830S (RE1815), 830A (RE1826) and 830W from Dai Nippon Ink & Chemicals, Inc., and RSL 1738 and YL-983U from Resolution) and bisphenol-A-type epoxies (such as YL-979 and 980 from Resolution). Further examples of commercially available epoxy resins include Epon 828, Epon 826, Epon 862 (all from Hexion Co., Ltd.), DER 331, DER 383, DER 332, DER 330-EL, DER 331-EL, DER 354, DER 321, DER 324, DER 29, DER 353 (all from Dow Chemical Co.), JER YX8000, JER RXE21, JER YL 6753, JER YL6800, JER YL980, JER 825, and JER 630 (all from Japan Epoxy Resins Co).

The bisphenol epoxies available commercially from Dai Nippon and noted above are promoted as liquid undiluted epichlorohydrin-bisphenol F epoxies having much lower viscosities than conventional epoxies based on bisphenol A epoxies and have physical properties similar to liquid bisphenol A epoxies. Bisphenol F epoxy has lower viscosity than bisphenol A epoxies, all else being the same between the two types of epoxies, which affords a lower viscosity and thus a fast flow underfill sealant material. The Epoxy Equivalent Weight (EEW), which is the molecular weight divided by the number of epoxy groups of these four bisphenol F epoxies is between 165 and 180. The viscosity at 25° C. is between 3,000 and 4,500 cps (except for RE1801 whose upper viscosity limit is 4,000 cps). The hydrolyzable chloride content is reported as 200 ppm for RE1815 and 830W, and that for RE1826 as 100 ppm.

The bisphenol epoxies available commercially from Resolution and noted above are promoted as low chloride containing liquid epoxies. The bisphenol A epoxies have an EEW (g/eq) of between 180 and 195 and a viscosity at 25° C. of between 100 and 250 cP. The total chloride content for YL-979 is reported as between 500 and 700 ppm, and that for YL-980 as between 100 and 300 ppm. The bisphenol F epoxies have an EEW (g/eq) of between 165 and 180 and a viscosity at 25° C. of between 30 and 60. The total chloride content for RSL-1738 is reported as between 500 and 700 ppm, and that for YL-983U as between 150 and 350 ppm.

In addition to the bisphenol epoxies, other epoxy compounds are contemplated for use as the epoxy component of invention formulations. For instance, cycloaliphatic epoxies, such as 3,4-epoxycyclohexylmethyl-3,4-epoxycyclohexylcarbonate, can be used. Also, monofunctional, difunctional or multifunctional reactive diluents may be used to adjust the viscosity and/or lower the glass transition temperature (Tg) of the resulting resin material. Exemplary reactive diluents include butyl glycidyl ether, cresyl glycidyl ether, o-cresyl glycidyl ether, polyethylene glycol glycidyl ether, polypropylene glycol glycidyl ether, and the like.

Other epoxies suitable for use herein include polyglycidyl derivatives of phenolic compounds, such as those available commercially under the tradename EPON, such as EPON 828, EPON 1001, EPON 1009, and EPON 1031 from Resolution; DER 331, DER 332, DER 334, and DER 542 from Dow Chemical Co.; and BREN-S from Nippon Kayaku. Other suitable epoxies include polyepoxides prepared from polyols and the like and polyglycidyl derivatives of phenol-formaldehyde novolacs, the latter of such as DEN 431, DEN 438, and DEN 439 from Dow Chemical. Cresol analogs are also available commercially under the tradename ARALDITE, such as ARALDITE ECN 1235, ARALDITE ECN 1273, and ARALDITE ECN 1299 from Ciba Specialty Chemicals Corporation. SU-8 is a bisphenol-A-type epoxy novolac available from Resolution. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Ciba Specialty Chemicals and PGA-X and PGA-C from the Sherwin-Williams Co.

In some embodiments, the epoxy component employed herein is a silane modified epoxy, e.g., a composition of matter that includes:
(A) an epoxy component embraced by the following structure:

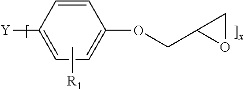

where:
   Y may or may not be present and when Y present is a direct bond, CH₂,

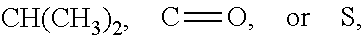

R₁ here is alkyl, alkenyl, hydroxy, carboxy and halogen, and
x here is 1-4;
(B) an epoxy-functionalized alkoxy silane embraced by the following structure:

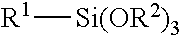

wherein
   R₁ is an oxirane-containing moiety and
   R₂ is an alkyl or alkoxy-substituted alkyl, aryl, or aralkyl group having from one to ten carbon atoms; and
(C) reaction products of components (A) and (B).

An example of one such silane-modified epoxy is formed as the reaction product of an aromatic epoxy, such as a bisphenol A, E, F or S epoxy or biphenyl epoxy, and epoxy silane where the epoxy silane is embraced by the following structure:

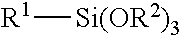

wherein
   R₁ is an oxirane-containing moiety, examples of which include 2-(ethoxymethyl) oxirane, 2-(propoxymethyl) oxirane, 2-(methoxymethyl) oxirane, and 2-(3-methoxypropyl) oxirane and
   R₂ is an alkyl or alkoxy-substituted alkyl, aryl, or aralkyl group having from one to ten carbon atoms.
      In one embodiment, R₁ is 2-(ethoxymethyl) oxirane and R₂ is methyl.

Idealized structures of the aromatic epoxy used to prepare the silane modified epoxy include

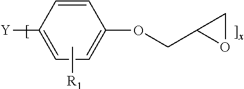

wherein
   Y may or may not be present, and when Y is present, it is a direct bond, CH₂,

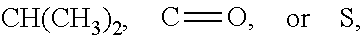

R¹ is alkyl, alkenyl, hydroxy, carboxy or halogen, and
x is 1-4.
   Of course, when x is 2-4, chain extended versions of the aromatic epoxy are also contemplated as being embraced by this structure.

For instance, a chain extended version of the aromatic epoxy may be embraced by the structure below

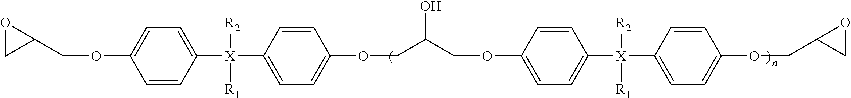

In some embodiments, the siloxane modified epoxy resin has the structure:

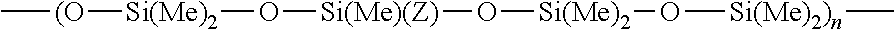

wherein:
   Z is —O—(CH₂)₃—O-Ph-CH₂-Ph-O—(CH₂—CH(OH)—CH₂—O-Ph-CH₂-Ph-O—)ₙ—CH₂— oxirane, and
   n falls in the range of about 1-4.

In some embodiments, the siloxane modified epoxy resin is produced by contacting a combination of the following components under conditions suitable to promote the reaction thereof:

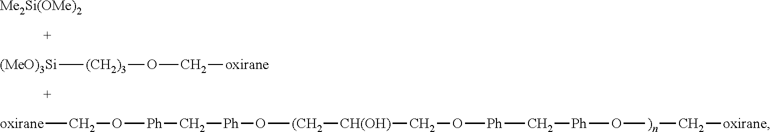

wherein “n” falls in the range of about 1-4.

The silane modified epoxy may also be a combination of the aromatic epoxy, the epoxy silane, and reaction products of the aromatic epoxy and the epoxy silane. The reaction products may be prepared from the aromatic epoxy and epoxy silane in a weight ratio of 1:100 to 100:1, such as a weight ratio of 1:10 to 10:1.

Acrylates useful as the curable resin component may be selected from a host of different compounds. As used herein, the terms acrylate and acrylic may be used interchangeably with regard to the monomer and monomer-containing component. Such terms are also considered to include (meth)acrylate and (meth)acrylic. Example polymerizable acrylate monomers include triethylene glycol di(meth)acrylate, tripropylene glycol di(meth)acrylate, tetra glycol di(meth)acrylate, diethylene glycol di(meth)acrylate, 1,4-butanediol di(meth)acrylate, 1,6-hexanediol di(meth)acrylate, pentaerythritol tetra(meth)acrylate, trimethylol propane tri(meth)acrylate, di-pentaerythritol monohydroxypenta(meth)acrylate, pentaerythritol tri(meth)acrylate, bisphenol-A-ethoxylate di(meth)acrylate, trimethylolpropane ethoxylate tri(meth)acrylate, trimethylolpropane propoxylate tri(meth)acrylate, and bisphenol-A-diepoxide di(methyl)acrylate.

Additionally, mono-functional (meth)acrylate monomers may be used, including tetrahydrofurane (meth)acrylates and di(meth)acrylates, hydroxypropyl (meth)acrylate, tetrahydrodicyclopentadienyl (meth)acrylate, triethylene glycol (meth)acrylate, and combinations thereof.

The curable compositions of the present invention may include a curable matrix-forming resin in the range of 1 up to 40 percent by weight of the total composition, preferably in the range of 5 up to 40 percent by weight of the total composition, preferably in the range of 5 up to 30 percent by weight of the total composition, preferably in the range of 10 up to 30 percent by weight of the total composition, and preferably in the range of 10 up to 25 percent by weight of the total composition.

For the purposes of this disclosure, the percent by weight of the composition, or percent by weight of the total composition, is calculated based upon the non-solvent components of the composition. This is sometimes referred to as the “solids” components of the composition, wherein the non-solvent components remain in the final solid film. It is to be understood, however, that certain components of the composition may be in liquid form, but are nevertheless counted as a “solid” because they form a part of the final, solid film product.

In some embodiments, the curable matrix-forming resin may include one or more epoxy resins. The one or more epoxy resins may be present in the range of 1 up to 40 percent by weight of the total composition, preferably in the range of 1 up to 30 percent by weight of the total composition, preferably in the range of 1 up to 20 percent by weight of the total composition, preferably in the range of 1 up to 10 percent by weight of the total composition, and preferably in the range of 5 up to 10 percent by weight of the total composition.

### Curing Agent

The compositions of the present invention also include one or more curing agents, such as a latent curing agent that is effective to promote the polymerization of the curable resin only at temperatures exceeding a threshold temperature. In some embodiments, the curing agents of the present invention are activated at temperatures exceeding 140° C. In some embodiments, the curing agents of the present invention are activated at temperatures exceeding 150° C. For the purposes hereof, the term “cure” is intended to mean a cross-linking reaction to form a tri-dimensional polymer network.

Applicant has found that restricting polymer matrix formation until sufficient temperature parameters have been met can assist in enhancing the effective thermal conductivity of the inorganic particulate filler dispersed in the system. Specifically, certain thermally conductive inorganic particulate filler may have surface coatings that impair metal-metal interaction. Examples of such particulate filler include metals and metal alloys, in some embodiments including copper, silver, aluminum, and combinations thereof. Removal of surface coatings from these particulated materials results in better contact among the metallic filler, and it has been found that the coating layer(s) can be reduced or eliminated by exposure to sufficiently elevated temperatures. Once the surface coating layer is removed from the particulate filler, the particles can more effectively interact with one another, and thereby transfer thermal energy more efficiently. However, it is an aspect of the invention that the de-coupling of the surface coating layers particles be accomplished prior to formation of the polymer matrix in order to promote metal-metal interactions while the filler is at least somewhat mobile within the monomer resin. Thus, the formation of the polymer matrix is preferably initiated at a temperature that is higher than that at which the surface coatings are caused to be de-coupled from the particles.

Applicant has found that, as temperatures exceed 140-150° C., surface layer coatings may be de-coupled from the particles, thereby enhancing heat transfer properties. As a result of enhanced heat transfer properties, equivalent or even higher thermal conductivity properties may be achieved in a thermally conductive film without increased concentration of thermally conductive particulate filler.

For the purposes of this disclosure, the term “de-couple” means to disassociate a surface coating from the particle surface.

In some embodiments, the curing agent is effective to promote the polymerization of the curable resin only at temperatures sufficient to substantially de-couple surface coating from the thermally conductive particulate filler dispersed in the curable composition. Preferably, the curing agent is effective to promote the polymerization of the curable resin only at temperatures sufficient to de-couple the surface coating from the thermally conductive particulate filler.

Epoxy cure agents may be employed in combination with epoxy monomer(s). Exemplary epoxy cure agents include ureas, aliphatic and aromatic amines, amine hardeners, polyamides, acid anhydrides, polyhydric phenols, imidazoles, dicyandiamides, hydrazides, urea-amine hybrid curing systems, free radical initiators (e.g., peroxy esters, peroxy carbonates, hydroperoxides, alkylperoxides, arylperoxides, azo compounds, and the like), organic bases, transition metal catalysts, phenols, acid anhydrides, Lewis acids, Lewis bases, and the like.

Specific examples of useful cure agents in the compositions of the present invention include the following structures:

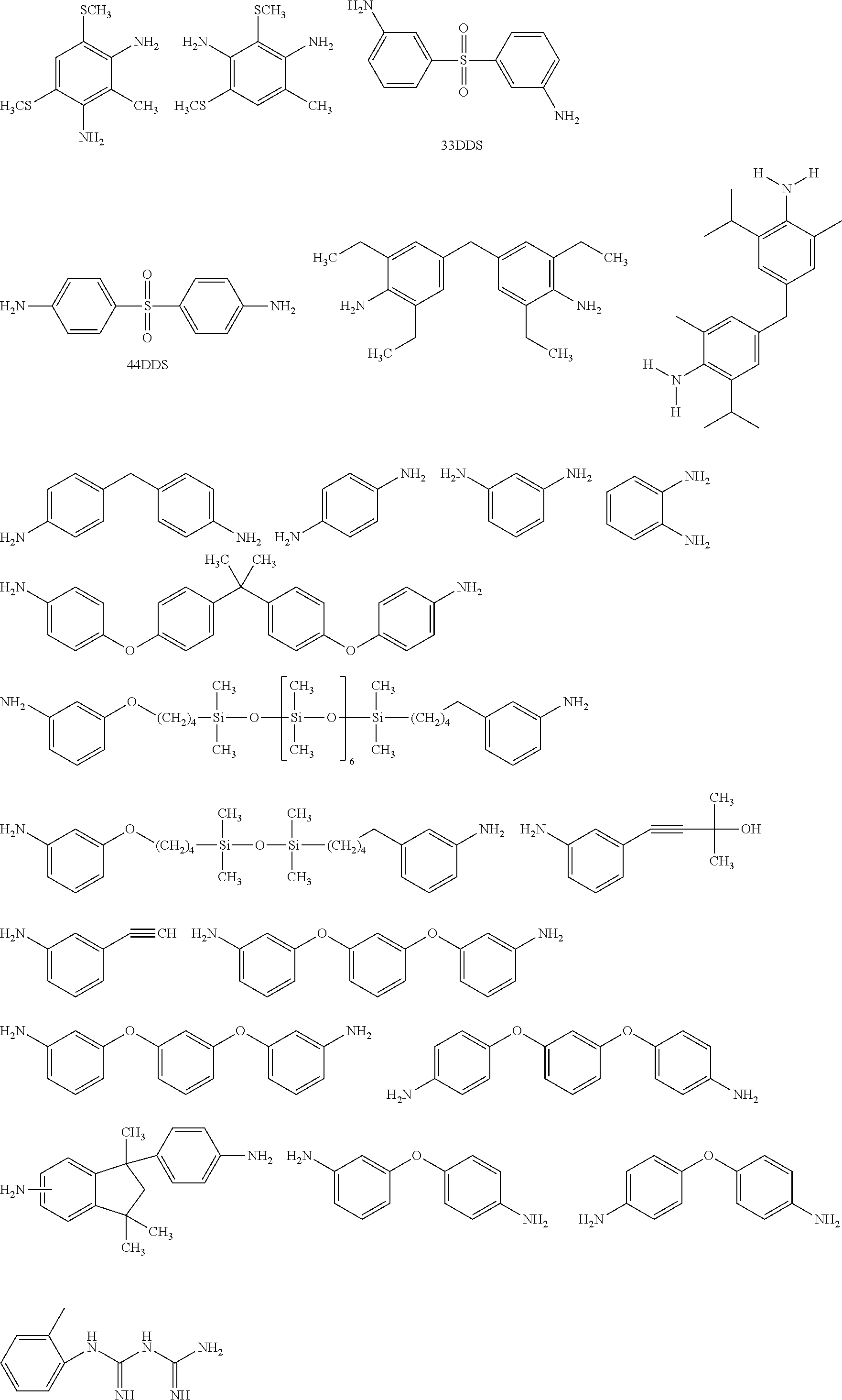

Cure agents may be present in the range of from 0.1 to 10 wt % of the total composition, and preferably in the range of from 0.1 and 5 wt % of the total composition. Typically, the cure agents may be present in the range of from 0.1 to 40 wt % of the curable resin in the composition, preferably in the range of from 0.2 to 30 wt % of the curable resin in the composition, preferably in the range of from 0.5 to 20 wt % of the curable resin in the composition, and preferably in the range of from 1 to 15 wt % of the curable resin in the composition. As described above, one or more cure agents are preferably present in the curable compositions effective to establish a resin polymerization onset temperature of at least 140° C., preferably at least 150° C.

### Thermally Conductive Particulate Filler

In order to enhance thermal conductivity, the thermally conductive compositions of the present invention preferably include thermally conductive particles dispersed therein. The particles may be both thermally conductive and electrically conductive. Alternatively, the particles may be thermally conductive and electrically insulating.

Conductive fillers contemplated for use herein include, for example, gold, silver, copper, platinum, palladium, nickel, aluminum, indium, alloy of nickel (e.g., alloy 42), alloy of zinc, alloy of iron, alloy of indium, silver-plated copper, silver-plated aluminum, bismuth, tin, bismuth-tin alloy, silver-plated fiber, silver-plated graphite, silver-plated silicon carbide, silver-plated boron nitride, silver-plated diamond, silver-plated alumina, silver-plated alloy 42, graphene, silver-plated graphene, graphene nanoplatelets, single and multi-wall carbon nanotubes, silver-coated polymer, cadmium and alloys of cadmium, lead and alloys of lead, antimony and alloys of antimony, boron nitride, aluminum nitride, alumina, alumina trihydrate, silicon, silicon carbide, graphite, diamond, magnesium oxide, magnesium hydroxide, zinc oxide, and the like, as well as mixtures of any two or more thereof. In some embodiments, the thermally conductive particulate filler has a melting point of at least 300° C., preferably at least 400° C., and preferably at least 500° C.

In some embodiments, the particulate thermally conductive filler may be substantially spherical, plate-like, rod-like, or combinations thereof. It is contemplated that a particle size distribution may be employed to fit the parameters of any particular application, although certain particle size distributions may be found to be more effective than others.

Thermally conductive particles used in the compositions of the present invention may be present in the range of less than 95 percent by weight of the total composition. In some embodiments, the thermally conductive particles may be present in the range of between 40 and 94 percent by weight of the total composition. In some embodiments, the thermally conductive particles may be present in the range of between 50 and 94 percent by weight of the total composition. In some embodiments, the thermally conductive particles may be present in the range of between 60 and 94 percent by weight of the total composition. In some embodiments, the thermally conductive particles may be present in the range of less than 85 percent by weight of the total composition. In some embodiments, the thermally conductive particles may be present in the range of between 40 and 84 percent by weight of the total composition. In some embodiments, the thermally conductive particles may be present in the range of between 50 and 84 percent by weight of the total composition. In some embodiments, the thermally conductive particles may be present in the range of between 60 and 84 percent by weight of the total composition.

The thermally conductive particles used in the compositions of the present invention have an average particle size (d₅₀) in the range of between 0.1 and 100 micrometers. In some embodiments, the average particle size is in the range of between 0.1 and 50 micrometers. In some embodiments, the average particle size is in the range of between 0.1 and 25 micrometers. In some embodiments, the average particle size is in the range of between 0.1 and 10 micrometers. In some embodiments, the average particle size is in the range of between 0.1 and 5 micrometers.

In a useful embodiment, the particulate thermally conductive filler may comprise a multi-modal particle size distribution, having discrete concentrations of particles with different average particle sizes. In some embodiments, a first portion of the thermally conductive filler may have an average particle size (d₅₀) of less than 1 micrometer, and a second portion of the thermally conductive filler may have an average particle size (d₅₀) of greater than 1 micrometer. In some embodiments, the first portion of the thermally conductive filler may comprise between 20 and 40 percent by weight of the total thermally conductive particulate filler. In some embodiments, the first portion of the thermally conductive filler may comprise between 25 and 35 percent by weight of the total thermally conductive particulate filler. Applicant has found that such particle size distributions can promote high thermal conductivity values without detracting from the desired physical properties of the composition.

It is desirable that the curable compositions of the present invention, when cured, exhibit a thermal conductivity of at least 5 W/m*K, more preferably at least 10 W/m*K, and more preferably at least 15 W/m*K.

In some embodiments, the thermally conductive particulate filler may be subjected to surface treatment or surface modification. Example surface treatment and surface modification include treatment with a silane coupling agent, phosphoric acid or a phosphoric acid compound, or a surfactant. The silane coupling agent may include at least one hydrolysable group such as an alkoxy group and an aryloxy group bonded to a silicon atom. Other examples include an alkyl group, and alkenyl group, and any aryl group bonded to the silicon atom. The thermally conductive particulate filler, whether or not surface treated or modified, may be blended with the curable resin and the curing agent by mixing the components in a mechanical mixer as needed to achieve a desired extent of dispersion of the particulate filler with the curable resin.

### Reaction Catalyst

A reaction catalyst may be employed to facilitate the cross-linking polymerization reaction of the curable resin. In some embodiments, the reaction catalyst facilitates the polymerization reaction at temperatures of at least 140° C., and more preferably at least 150° C. The reaction catalyst may be referred to as a cure accelerator. In some embodiments, the cure accelerator may be selected from tertiary amines, imidazole derivatives, and combinations thereof. Example tertiary amines include trimethylamine, tri-ethlyamine, tetraethylmethylenediamine, tetramethylpropane-1,3-diamine, tetra-methylhexane-1,6-diamine, pentamethyldiethylenetriamine, bis(2-dimethylaminoethyl) ether, ethylene glycol (3-dimethyl)aminopropyl ether, dimethyl-aminoethanol, dimethylaminoethyoxyethanol, trietheylenediamine, and hexamethylenetriamine.

Further example catalysts useful in the curable compositions of the present invention include the following structures:

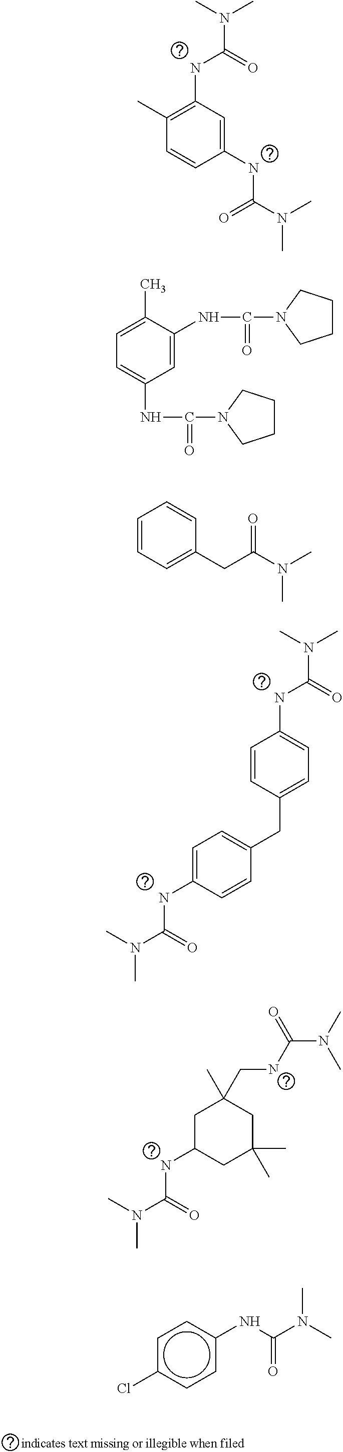

As described herein, formulating a curable composition that delays onset of the polymerization reaction to elevated temperatures, such as temperatures exceeding 140° C., facilitates particle-particle interaction prior to network formation. The interaction is facilitated by reducing or eliminating oxidation at the particle surface, which is accomplished by exposure to the high temperatures prior to network formation. With such oxidation reduced or eliminated, the particle-particle interaction can remain post-network formation. For the purposes hereof, the term “reducing or eliminating oxidation” means reducing the average concentration of oxygen atoms associated with thermally conductive particles in the curable composition by at least 20%.

### Other Additives

In addition to the curable resin, the cure agent, and the thermally conductive particulate filler, the compositions of the present invention may further include additives such as an organic solvent such as methyl ethyl ketone, a curing catalyst such as that described above, a viscosity modifier, an antioxidant, an adhesion promoter, a wetting agent, a dispersant, a flame retardant, a corrosion inhibitor, a pigment, and a stress relaxing agent. Additives that remain in the cured film are considered “solids”.

### Cured Composition

The curable compositions of the present invention, when cured, may form a film-like adhesive. For the purposes hereof, the term “film” means a thin film having a thickness of less than 250 micrometers. In some embodiments, the film formed from the curable compositions of the present invention, alone or in combination, may be disposed at a surface of a substrate, such as a silicon substrate of an electronic package. The film may also be applied onto a surface of a release-treated substrate liner for ease of handling and application to the package substrate. Example release-treated films include release-treated polypropylene, release-treated polyethylene, and release-treated polyethylene terephthalate.

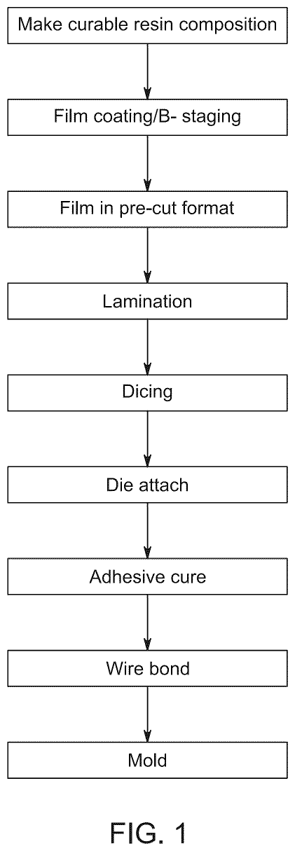

The compositions of the present invention exhibit good flowability at relatively low temperatures, such as temperatures below 80° C. This facilitates processing of the compositions into die attach films, including the step of laminating the compositions to a substrate. The flow diagram of FIG. 1 illustrates an example process of attaching a die to a substrate using the die attach films of the present invention. The attach films are prepared from a curable resin composition, which is formed by mixing the components, including the thermally conductive particulate filler, into a slurry in a mixing apparatus.

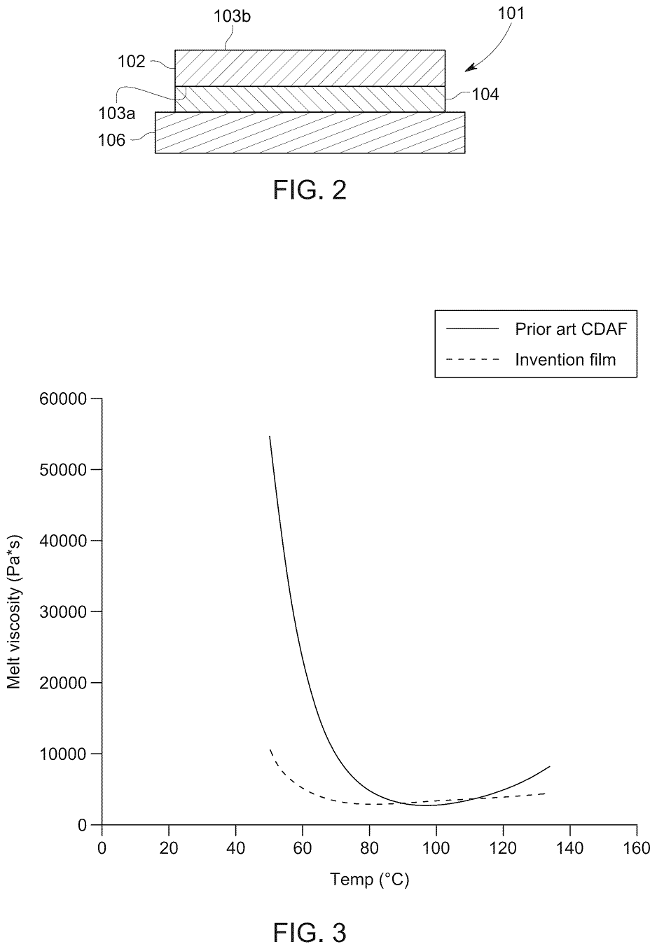

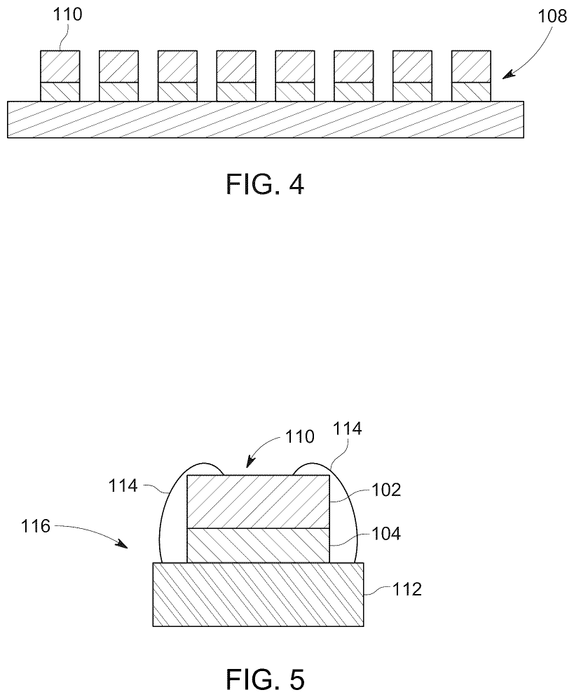

Generally, an assembly 101 as illustrated in FIG. 2 may be prepared by applying the curable resin composition to a semiconductor substrate or silicon wafer 102, such as by ink jet printing, stencil printing, screen printing, or spray coating. The application preferably uniformly coats an application surface of the substrate, and may be partially cured, or B-staged, into an adhesive layer 104. Alternatively, the curable composition may first be applied to a support layer 106, such as a dicing tape, and then thermocompression bonded onto the application surface 103a of substrate 102. Support layer 106 may, in some embodiments, be a polyolefin film, such as one or more layers of polyethylene, polyvinyl chloride, polybutene, polybutadiene, polyurethane, polyester, polyamide, and copolymers thereof.

Examples of substrate 102 include a semiconductor wafer in which a circuit surface 103b may support a semiconductor circuit, with the wafer substrate being formed from silicon, SiC, or GaN. In some embodiments, adhesive layer 104 may be formed by a single layer of curable composition, or two or more layers may be laminated to substrate 102. One or more layers of curable composition may be laminated to one or both of substrate 102 and support layer 106 to a desired thickness under laminating conditions, such as temperatures of between 50° C. and 130° C. along with the application of pressure to, for example, circuit surface 103b of substrate 102. During lamination, the curable composition softens and wets application surface 103a to adhere substrate 102 to support layer 106.

When the curable composition is heated in accordance with ASTM D4440, the melt viscosity changes by less than 100% between 5° and 130° C. In some embodiments, the melt viscosity changes by less than 90% between 5° and 130° C. In some embodiments, the melt viscosity changes by less than 80% between 5° and 130° C. In some embodiments, the melt viscosity changes by less than 75% between 5° and 130° C. In some embodiments, the melt viscosity is less than 50,000 Pa*s at 50° C., as tested by ASTM D4440. In some embodiments, the melt viscosity is less than 20,000 Pa*S at 50° C., as tested by ASTM D4440.

FIG. 3 illustrates a melt viscosity comparison of a curable composition of the present invention to a conventional adhesive composition that requires significantly higher loading of thermally conductive particulate filler in order to achieve suitable thermal conductivity properties. The comparison illustrates how the relatively low particulate filler loading of the present invention preserves a low melting viscosity at low temperatures while nevertheless exhibiting high thermal conductivity properties.

Following lamination, substrate 102 and adhesive layer 104 are diced using a dicing saw to form a semiconductor chip 108 having the semiconductor substrate 102 and adhesive layer 104 separated into distinct regions or dies 110 on support layer 106. After dicing is complete, the chip dies 110 may be removed from support layer 106 by a process known as die pickup or die pick and place. Die pickup is typically accomplished through the use of pick and place equipment to lift the individual dies from support layer 106 with suction force. The pick and place equipment then mounts the die 110 to a wiring board 112, typically through thermocompression, with adhesive layer 104 serving as the die attach medium. Example die attach conditions include temperatures of between 100° C. and 130° C. with about 10 N applied pressure. Wiring board 112 may be used to form semiconductor circuits with one or more wires 114 bonded between circuit surface 103b of substrate 102 and wiring board 112. The completed wire connection to wiring board 112 forms electronic package 116.

To fully secure die 110 to wiring board 112, adhesive layer 104 is preferably cured through a thermal cure, optionally including applied pressure to one or more of die 110 and wiring board 112. The thermal cure may include increasing the temperature of adhesive layer 104 to at least 140° C., and preferably at least 150° C. The cure conditions may be established in a cure oven with a temperature of between 140° C. and 180° C., and preferably between 150° C. and 175° C. for a time period sufficient to bring the temperature of adhesive layer 104 to or above the thresholds described above. In some embodiments, the time period is between 10 and 120 minutes.

In some embodiments, wiring board 112 and die 110 may be sealed with a sealing resin in the form of a mold. Sealing electronic package 116 may be performed by methods known by those of ordinary skill in the art.

### EXAMPLES

The following examples are intended to assist one skilled in the art to better understand and practice the present invention. The scope of the invention is not limited by the examples, but is defined in the appended claims. All parts and percentages are based on weight of solids unless otherwise stated, and do not include solvents or other liquid materials which may be present to facilitate storage and dispensation of the curable compositions. The thermal conductivity values provided in each example represent the thermal conductivity of the cured film following polymerization of the curable composition.

### Raw Materials

Epalloy 5200 is an epoxy resin.

Epoxy A is a chain extended epoxy with CTBN rubber.

EP7 is a chain extended epoxy solution at 50% solids in methyl ethyl ketone solvent.

Epoxy B is a liquid epoxy resin at room temperature.

N665 is an epoxy resin solution at 70% solids in methyl ethyl ketone solvent.

Erisys RDGE/H is a low viscosity aromatic difunctional epoxy resin including resorcinol diglycidyl ether.

SG-80H is a polyacrylate resin.

Resin A is a bismaleimide resin.

Nano Dicy is a dicyandiamide epoxy curing agent having a particle size of 1-2 μm.

Dodecenylsuccinic anhydride is a long-chain aliphatic anhydride epoxy resin reaction catalyst.

Cure Agent A is a 2, 4′ toluene bis dimethyl urea curing agent.

Cure Agent B is a dicyandiamide epoxy curing agent.

Cure Agent C is an aromatic amine curing agent.

Filler 1 is particulate silver with an average particle size of 1.9 μm.

Filler 2 is a particulate silver with an average particle size of 1.5 μm.

Filler 3 is a particulate silver with an average particle size of 0.8 μm.

Silane z 6040 is a silane adhesion promoter.

MEK is methyl ethyl ketone solvent.

Each of the Example compositions were prepared by adding the weighed ingredients into a vessel, and stirring the mixture using a speed mixer at 2,000 rpm for 2-3 minutes at ambient room temperature until the composition is well mixed into a slurry. The slurry was then coated upon a release liner film with a doctor blade to a thickness of between 10-100 μm and dried in an oven at 190° F. for 4 minutes to remove the solvent. After the solvent was evaporated, the film was cured at 200° C. for 60 minutes.

The polymerization onset temperature of each example composition was measured using a differential scanning calorimeter (DSC), with a temperature ranging from ambient room temperature to 300° C., pursuant to ASTM E793.

The thermal conductivity of each example composition was measured using a laser flash method, pursuant to ASTM E1461.

### Example 1

| Component | Weight (parts) |
|---|---|
| Epoxy A | 2.4 |
| Epalloy 5200 | 1.0 |
| SG-80H | 1.1 |
| Resin A | 2.0 |
| Nano dicy | 0.2 |
| Cure Agent A | 0.1 |
| Dodecenylsuccinic anhydride | 1.0 |
| Filler 3 | 26.1 |
| Filler 1 | 66.1 |
| Polymerization onset temp < 140° C. | |
| Thermal Conductivity = 3 W/m*K | |

### Example 2

| Component | Weight (parts) |
|---|---|
| Epoxy A | 9.0 |
| N665 | 1.0 |
| Epoxy B | 0.5 |
| EP7 | 1.0 |
| SG-80H | 1.1 |
| Resin A | 2.5 |
| Cure Agent B | 0.4 |
| Cure Agent A | 0.2 |
| Filler 3 | 25 |
| Filler 1 | 40 |
| Filler 2 | 20 |
| Silane z 6040 | 0.5 |
| Polymerization onset temp. < 140° C. | |
| Thermal Conductivity = 1.1 W/m*K | |

### Example 3

| Component | Weight (parts) |
|---|---|
| Epoxy A | 9.0 |
| N665 | 1.0 |
| Epoxy B | 0.5 |
| EP7 | 1.0 |
| SG-80H | 1.1 |
| Resin A | 2.5 |
| Cure Agent A | 0.9 |
| Filler 3 | 25 |
| Filler 1 | 40 |
| Filler 2 | 20 |
| Silane z 6040 | 0.5 |
| Polymerization onset temp. > 140° C. | |
| Thermal Conductivity = 10 W/m*K | |

### Example 4

| Component | Weight (parts) |
|---|---|
| Epoxy A | 4.0 |
| Epoxy B | 1.8 |
| EP7 | 0.9 |
| SG-80H | 1.0 |
| Cure Agent C | 0.4 |
| Cure Agent A | 0.1 |
| Filler 3 | 22.8 |
| Filler 1 | 59.1 |
| Silane z 6040 | 0.5 |
| Polymerization onset temp > 140° C. | |
| Thermal Conductivity = 11.3 W/m*K | |

### Example 5

| Component | Weight (parts) |
|---|---|
| Epoxy A | 4.5 |
| Erisys RDGE/H | 2 |
| EP7 | 1 |
| SG-80H | 0.9 |
| Cure Agent A | 1.3 |
| Filler 3 | 25 |
| Filler 1 | 66.5 |
| Polymerization onset temp. > 140° C. | |
| Thermal Conductivity = 33 W/m*K | |

### Example 6

| Component | Weight (parts) |
|---|---|
| Epoxy A | 4.5 |
| Erisys RDGE/H | 2.0 |
| EP7 | 1.0 |
| SG-80H | 1.1 |
| Cure Agent C | 0.4 |
| Cure Agent A | 0.1 |
| Filler 3 | 25 |
| Filler 1 | 66.5 |
| Polymerization onset temp. > 140° C. | |
| Thermal Conductivity = 17 W/m*K | |

Table 1 summarizes data from Examples 1-6 above:

TABLE 1

| | | | Onset Temp | |
|---|---|---|---|---|
| Example | Wt. % Filler | Cure Agent | (° C.) | T_{c} (W/m*K) |
| 1 | 92.2 | A, Nano Dicy | <140 | 3.0 |
| 2 | 84.0 | A, B | <140 | 1.1 |
| 3 | 83.7 | A | >140 | 10 |
| 4 | 90.4 | A, C | >140 | 11.3 |
| 5 | 90.4 | A | >140 | 33 |
| 6 | 91.0 | A, C | >140 | 17 |

Table 1 illustrates that the compositions of Examples 3-6, which exhibit polymerization onset temperatures of at least 140° C. surprisingly exhibit substantially increased thermal conductivity values in comparison to the compositions of Examples 1 and 2. In particular, the compositions of Examples 4-6 contain comparable, and even somewhat lower concentrations of thermally conductive particulate filler than the composition of Example 1, but nevertheless exhibit substantially higher thermally conductivity values. The same is true for the composition of Example 3, which contains a comparable concentration of thermally conductive particulate filler as in the composition of Example 2, but nevertheless exhibits a substantially higher thermal conductivity.

In the example compositions, cure agents “B” and “Nano Dicy” suppressed the polymerization onset temperature in contrast to using cure agents A and C alone or in combination with one another. The elevated polymerization onset temperature of Examples 3-6 has the unexpected benefit of enhanced thermal conductivity without increased particulate filler concentration. Because the compositions of Examples 3-6 do not require increased particulate filler loading, it can be expected that good handling, wettability, and adhesion properties comparable to known films are exhibited by the compositions and films of the present invention, while also providing superior thermal conductivity.

1. A thermally conductive curable composition, comprising:
an epoxy resin;
thermally conductive particulate filler being present at less than 95 wt. % by solids of the composition, the thermally conductive particulate filler being selected from a metal, a metal alloy, a metal oxide, and combinations thereof; and
a curing agent effective to cure the epoxy resin,
wherein the curing agent and epoxy resin are selected so that the composition exhibits a polymerization onset temperature of at least 140° C., and, when cured, the composition exhibits a thermal conductivity of at least 5 W/m*K.

2. The thermally conductive curable composition as in claim 1 wherein the thermally conductive particulate filler is present at less than 80 wt. % by solids of the composition.

3. The thermally conductive curable composition as in claim 1 wherein the thermally conductive particulate filler includes a metal selected from copper, silver, aluminum, and combinations thereof.

4. The thermally conductive curable composition as in claim 3 wherein the thermally conductive particulate filler has a melting point of at least 300° C.

5. The thermally conductive curable composition as in claim 1 wherein the curing agent includes one or more of an aromatic substituted urea and an aromatic amine.

6. The thermally conductive curable composition as in claim 1 having a melt viscosity change of less than 75% between 50-130° C.

7. The thermally conductive curable composition as in claim 1 having a melt viscosity of less than 20000 Pa at 50° C.

8. The thermally conductive curable composition as in claim 1 wherein, when cured, the composition exhibits a thermal conductivity of at least 10 W/m*K.

9. A thermally conductive adhesive composition, comprising:
1-40 wt % by solids of a curable resin;
0.1-2 wt % by solids of a curing agent effective to cure the resin, wherein the curing agent and the resin are selected so that the composition exhibits a polymerization onset temperature of at least 140° C.; and
less than 95 wt % by solids of a thermally conductive particulate metallic filler, wherein the composition, when cured, exhibits a thermal conductivity of at least 5 W/m*K.

10. The thermally conductive adhesive composition as in claim 9 wherein the curable resin includes an epoxy.

11. The thermally conductive adhesive composition as in claim 10 wherein the curable resin includes an acrylate.

12. The thermally conductive adhesive composition as in claim 11 wherein the thermally conductive particulate metallic filler includes silver.

13. The thermally conductive adhesive composition as in claim 12 wherein the curing agent includes one or more of an aromatic substituted urea and an aromatic amine.

14. The thermally conductive adhesive composition as in claim 9, including less than 80 wt % by solids of the thermally conductive particulate metallic filler.

15. An electronic package, comprising:
a silicon substrate;
the thermally conductive curable composition of claim 1 applied to a surface of the silicon substrate; and
an electronic component connected to the silicon substrate by the thermally conductive curable composition when in a cured condition.

16. The electronic package as in claim 15 wherein the thermally conductive curable composition is disposed as a film onto the surface of the silicon substrate.

17. A method for forming a thermally conductive film, the method comprising:
providing a thermally conductive curable composition including:
an epoxy resin;
thermally conductive particulate filler being present at less than 95 wt. % by solids of the curable composition; and
a curing agent effective to cure the epoxy resin only at cure temperatures of at least 140° C.;
applying the thermally conductive curable composition to a substrate surface in a layer having a thickness of less than 250 micrometers;
heating the curable composition to a temperature sufficient to de-oxidize the thermally conductive particulate filler;
curing the thermally conductive curable composition.

18. The method as in claim 17 wherein curing the thermally conductive curable composition includes heating the curable composition to a cure temperature of at least 140° C.

19. The method as in claim 18 wherein the temperature sufficient to de-oxidize the thermally conductive particulate filler is less than the cure temperature.

20. The method as in claim 19 wherein the substrate is a silicon wafer board, and the combination of the silicon wafer board and the curable composition is a die.

21. The method as in claim 20, including, prior to heating the curable composition to the cure temperature, attaching the die to a wiring board.
